(19) United States
(12) Patent Application Publication
(10) Pub. No.: US 2023/0364910 A1
(43) Pub. Date: Nov. 16, 2023

(54) SINGLE CRYSTAL SILICON SUBSTRATE, LIQUID DISCHARGE HEAD, AND METHOD FOR MANUFACTURING SINGLE CRYSTAL SILICON SUBSTRATE

(71) Applicant: SEIKO EPSON CORPORATION, TOKYO (JP)

(72) Inventors: Shinichi YOTSUYA, CHINO-SHI (JP); Masahiro FUJII, SHIOJIRI-SHI (JP); Koji KITAHARA, INA-SHI (JP)

(21) Appl. No.: 18/316,423

(22) Filed: May 12, 2023

(30) Foreign Application Priority Data
May 12, 2022 (JP) 2022-078680

(51) Int. Cl. B41J 2/16; B41J 2/14

(52) U.S. Cl. CPC B41J 2/161; B41J 2/14201; B41J 2/1629; B41J 2/1643; B41J 2002/14306

(57) ABSTRACT

A single crystal silicon substrate at least a part of which constitutes a flow path for liquid includes a through-hole constituting a part of the flow path and extending through the single crystal silicon substrate in a direction intersecting a substrate surface of the single crystal silicon substrate. The through-hole is formed by metal-assisted chemical etching, and includes a striped portion in which at least one of a concave portion or a convex portion along a direction in which the liquid flows extends.

The present application is based on, and claims priority from JP Application Serial Number 2022-078680, filed May 12, 2022, the disclosure of which is hereby incorporated by reference herein in its entirety.

### BACKGROUND

### 1. Technical Field

The present disclosure relates to a single crystal silicon substrate, a liquid discharge head, and a method for manufacturing a single crystal silicon substrate.

### 2. Related Art

In the past, various silicon substrates have been used. Such silicon substrates are desirably used in various liquid discharge heads such as an ink-jet head that discharges ink as liquid. Among such silicon substrates, there is a silicon substrate at which a through-hole is formed through which liquid flows. For example, in IEEE Transactions MEMS00 Proceedings, a method is disclosed for forming a through-hole through which liquid is poured at a silicon substrate by using Si-Deep-RIE.

Since Si-Deep-RIE of IEEE Transactions MEMS00 Proceedings is an etching method in which formation of a side wall protective film and etching are repeated every about 1 μm, irregularities called scallops are formed at a side wall of the formed through-hole in a direction intersecting a depth direction of the through-hole. Since the irregularities are formed along the direction intersecting the depth direction, which is a direction in which the liquid flows, when the liquid flows through the through-hole, a turbulent flow may occur to disturb the flow of the liquid, and air bubbles, foreign matter, and the like may remain in the irregularities and be difficult to remove to affect the flow of the liquid.

### SUMMARY

Accordingly, a single crystal silicon substrate according to the present disclosure for resolving the above problem is a single crystal silicon substrate at least a part of which constitutes a flow path for liquid, the single crystal silicon substrate including a through-hole constituting a part of the flow path and extending through the single crystal silicon substrate in a direction intersecting a substrate surface of the single crystal silicon substrate, wherein the through-hole is formed by metal-assisted chemical etching, and includes a striped portion in which at least one of a concave portion or a convex portion along a direction in which the liquid flows extends.

Additionally, a method for manufacturing a single crystal silicon substrate according to the present disclosure for resolving the above problem includes forming a catalyst film in an etching target region of a catalyst film forming surface of a substrate surface of a single crystal silicon substrate, and forming a through-hole extending through the single crystal silicon substrate in a direction intersecting the substrate surface, by bringing the single crystal silicon substrate with the catalyst film formed into contact with an etching solution to etch the etching target region, wherein while forming the through-hole, a striped portion is formed in which at least one of a concave portion or a convex portion along an extending direction of the through-hole extends.

### BRIEF DESCRIPTION OF THE DRAWINGS

FIG. 1 is a bottom view of a liquid discharge head of an example of the present disclosure and an enlarged view of a partial region X thereof.

FIG. 2 is a side cross-sectional view of the liquid discharge head of FIG. 1.

FIG. 3 is a perspective view of the liquid discharge head of FIG. 1 from a bottom surface side of a flow path substrate.

FIG. 4 is a diagram illustrating a manufacturing process of the flow path substrate of the liquid discharge head of FIG. 1.

FIG. 5 is a flowchart illustrating a method for manufacturing the flow path substrate and a sealing plate of the liquid discharge head of FIG. 1.

FIG. 6 is a photograph of irregularities formed at an edge portion of a catalyst film.

FIG. 7 is a photograph of an inside of a nozzle of the flow path substrate of the liquid discharge head of FIG. 1.

FIG. 8 is a perspective view of the sealing plate of the liquid discharge head of FIG. 1.

FIG. 9 is a diagram illustrating a manufacturing process of the sealing plate of the liquid discharge head of FIG. 1.

FIG. 10 is a flowchart illustrating a method for manufacturing the entire liquid discharge head of FIG. 1.

### DESCRIPTION OF EXEMPLARY EMBODIMENTS

First, the present disclosure will be schematically described.

A single crystal silicon substrate according to a first aspect of the present disclosure for resolving the above problem is a single crystal silicon substrate at least a part of which constitutes a flow path for liquid, the single crystal silicon substrate including a through-hole constituting a part of the flow path and extending through the single crystal silicon substrate in a direction intersecting a substrate surface of the single crystal silicon substrate, wherein the through-hole is formed by metal-assisted chemical etching, and includes a striped portion in which at least one of a concave portion or a convex portion along a direction in which the liquid flows extends.

According to the present aspect, the through-hole is formed by metal-assisted chemical etching, and includes the striped portion in which at least one of the concave portion or the convex portion along the direction in which the liquid flows extends. Therefore, it is possible to form the striped portion along the direction in which the liquid flows with a narrow formation pitch by metal-assisted chemical etching, and it is possible to improve the flow of the liquid in the through-hole by the striped portion along the direction in which the liquid flows with the narrow formation pitch.

A single crystal silicon substrate according to a second aspect of the present disclosure is the single crystal silicon substrate according to the first aspect, wherein at least one of a plurality of the concave portions or a plurality of the convex portions are provided side by side at the through-hole when viewed in an extending direction of the through-hole, and a formation pitch between the concave portions adjacent to each other or between the convex portions adjacent to each other is from 10 nm to 300 nm.

According to the present aspect, the formation pitch of the striped portion is from 10 nm to 300 nm. When the formation pitch of the striped portion is too large, there is a possibility that turbulence occurs or bubbles, foreign matter, and the like remain in the concave portion or the convex portion, and when the formation pitch of the striped portion is too small, there is a possibility that an effect of forming the striped portion is insufficient, however, by setting the formation pitch of the striped portion to be from 10 nm to 300 nm, it is possible to suitably improve the flow of the liquid in the through-hole.

A liquid discharge head according to a third aspect of the present disclosure includes the first or second single crystal silicon substrate, and a cavity substrate including a conductive portion forming surface at which a piezoelectric element and a conductive portion electrically coupled to the piezoelectric element are formed, and a flow path forming surface at least a part of which constitutes the flow path and that is opposite to the conductive portion forming surface, wherein the conductive portion forming surface or the flow path forming surface is bonded to the substrate surface with the flow path of the flow path forming surface communicating with the through-hole.

According to the present aspect, the conductive portion forming surface is bonded to the substrate surface by the above single crystal silicon substrate and the cavity substrate, and the flow path of the flow path forming surface is configured to communicate with the through-hole. Thus, it is possible to manufacture a liquid discharge head in which the flow of the liquid in the through-hole is improved.

A method for manufacturing a single crystal silicon substrate according to a fourth aspect of the present disclosure includes forming a catalyst film in an etching target region of a catalyst film forming surface of a substrate surface of a single crystal silicon substrate, and forming a through-hole extending through the single crystal silicon substrate in a direction intersecting the substrate surface, by bringing the single crystal silicon substrate with the catalyst film formed into contact with an etching solution to etch the etching target region, wherein while forming the through-hole, a striped portion is formed in which at least one of a concave portion or a convex portion along an extending direction of the through-hole extends.

According to the present aspect, the catalyst film is formed in the etching target region of the catalyst film forming surface, the etching target region of the single crystal silicon substrate with the catalyst film formed is etched to form the through-hole, and the striped portion along the extending direction is formed along with the formation of the through-hole. For this reason, it is possible to form the elaborate striped portion along the extending direction with the narrow formation pitch at the through-hole. Therefore, it is possible to improve the flow of the liquid in the through-hole.

A method for manufacturing a single crystal silicon substrate according to a fifth aspect of the present disclosure is the method according to the fourth aspect, wherein while forming the through-hole, the through-hole is formed by metal-assisted chemical etching.

According to the present aspect, the through-hole is formed by metal-assisted chemical etching. For this reason, it is possible to suitably form the elaborate striped portion along the extending direction with the narrow formation pitch at the through-hole. Therefore, it is possible to improve the flow of the liquid in the through-hole.

A method for manufacturing a single crystal silicon substrate according to a sixth aspect of the present disclosure is the method according to the fifth aspect, wherein while forming the catalyst film, the catalyst film is formed by an electroless plating method or a vapor deposition method.

According to the present aspect, the catalyst film is formed by an electroless plating method or a vapor deposition method. By manufacturing a single crystal silicon substrate in this manner, the single crystal silicon substrate can be manufactured particularly easily and with high accuracy.

A method for manufacturing a single crystal silicon substrate according to a seventh aspect of the present disclosure is the method according to any one of the fourth to sixth aspects, further including forming a pattern with a resist before the formation of the catalyst film, and removing the resist after the formation of the catalyst film.

According to the present aspect, the pattern is formed with the resist before the catalyst film is formed, and the resist is removed after the catalyst film is formed. By adopting such a method, the single crystal silicon substrate can be manufactured easily.

A method for manufacturing a single crystal silicon substrate according to an eighth aspect of the present disclosure is the method according to any one of the fourth to sixth aspects, wherein a side wall of the through-hole is constituted by a vertical side wall angled at 90° plus or minus 2° with respect to the substrate surface.

According to the present aspect, the side wall of the through-hole is constituted by the vertical side wall angled at 90° plus or minus 2° with respect to the substrate surface. Therefore, expansion of the substrate surface can be suppressed, and the single crystal silicon substrate can be made small.

A method for manufacturing a single crystal silicon substrate according to a ninth aspect of the present disclosure is the method according to any one of the fourth to sixth aspects, wherein while forming the through-hole, the through-hole is formed by removing the catalyst film before the single crystal silicon substrate is penetrated, and removing a part of the substrate surface on a side of a surface opposite to the catalyst film forming surface to a position where the single crystal silicon substrate is penetrated.

According to the present aspect, the catalyst film is removed before the single crystal silicon substrate is penetrated, and a part of the substrate surface on the side of the surface opposite to the catalyst film forming surface is removed to the position where the single crystal silicon substrate is penetrated. By adopting such a method, the single crystal silicon substrate can be manufactured easily.

A method for manufacturing a single crystal silicon substrate according to a tenth aspect of the present disclosure is the method according to any one of the fourth to sixth aspects, further including forming an inclined through-hole including an inclined side wall more inclined than a side wall of the through-hole with respect to the substrate surface, by subjecting a crystal anisotropic etching target region of the substrate surface to crystal anisotropic etching.

According to the present aspect, the crystal anisotropic etching target region of the substrate surface is subjected to crystal anisotropic etching, thereby forming the inclined through-hole including the inclined side wall more inclined than the side wall of the through-hole with respect to the substrate surface. Therefore, for example, when a constituent member is disposed at a through-hole, by forming an inclined through-hole that is widened toward an end, the constituent member can be suitably disposed at the inclined through-hole.

A method for manufacturing a single crystal silicon substrate according to an eleventh aspect of the present disclosure is the method according to the tenth aspect, wherein while forming the inclined through-hole, an alkaline aqueous solution is used as the etching solution.

According to the present aspect, an alkaline aqueous solution is used as the etching solution when forming the inclined through-hole. Therefore, the inclined through-hole can be easily formed.

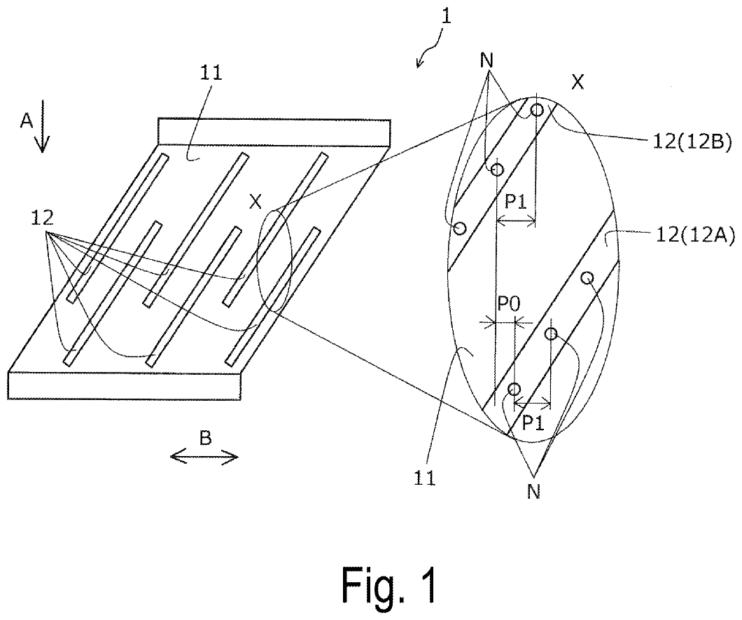

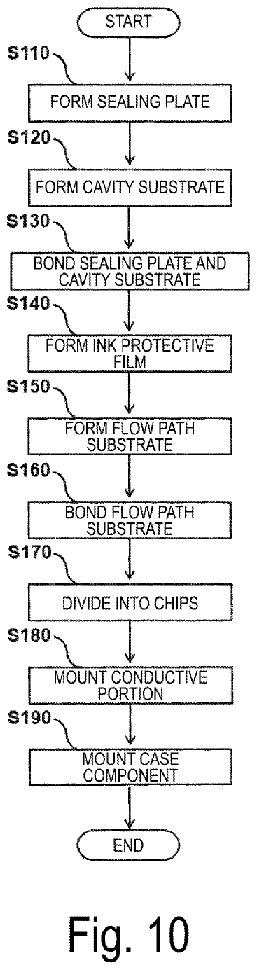

Next, a liquid discharge head 1 of an example of the present disclosure will be described in detail with reference to FIG. 1 to FIG. 10. Note that, in the following figures, in order to facilitate understanding of structure of the liquid discharge head 1, some members are simplified, some members are omitted, and an aspect ratio of some members is changed.

FIG. 1 illustrating the liquid discharge head 1 of the present example is a bottom view of an ink-jet head capable of forming an image by discharging ink as liquid from nozzles N onto a medium, while transporting the medium in a moving direction A, or while the liquid discharge head 1 itself is moving in the moving direction A with respect to the stopped medium. The liquid discharge head 1 of the present example is a so-called line head in which the nozzles N are provided corresponding to the entire medium in a width direction B intersecting the moving direction A.

When the plurality of nozzles N are arranged at a nozzle forming surface 11 that is a bottom surface of the line head, the nozzles N can be arranged most simply by arranging the nozzles N in the width direction B. However, when the nozzles N are arranged in such a manner, a pitch between the nozzles N adjacent in the width direction B is widened. When the pitch between the adjacent nozzles N is widened, a resolution is lowered. Therefore, in the liquid discharge head 1 of the present example, a plurality of nozzle rows 12 in which the nozzles N are aligned in straight lines are arranged so as to be inclined with respect to the moving direction A.

As illustrated in an enlarged view of the region X in FIG. 1, in the liquid discharge head 1 of the present example, an interval between the nozzles N in the width direction B of each nozzle row 12 is a pitch P1. Further, since the adjacent nozzle rows 12 are configured to discharge the same ink, and a configuration is adopted in which positions of the nozzles N are shifted by half the pitch P1 for each nozzle row 12 between the nozzle rows 12 adjacent to each other in the width direction B, an interval between the nozzles N in the width direction B of the liquid discharge head 1 is a pitch P0, which is half the pitch P1. In the liquid discharge head 1 of the present example, by arranging the nozzle rows 12 as described above, the resolution is increased to 1200 dpi (dot per inch) with the pitch of P0.

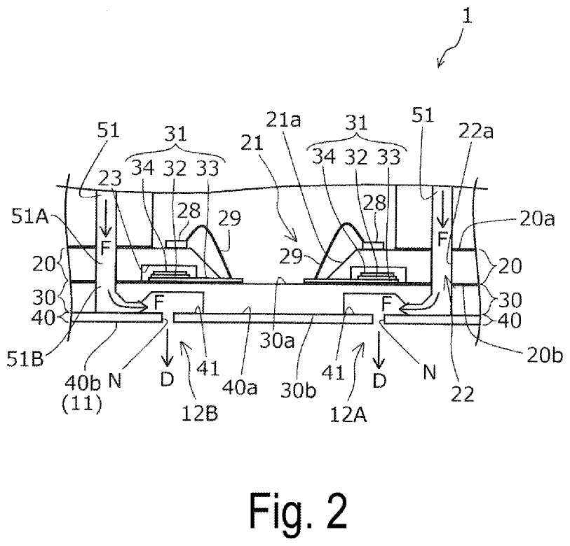

Note that, in addition to arranging the nozzle rows 12 so as to be inclined with respect to the moving direction A as described above, the interval between the adjacent nozzles N is narrowed, and thus it is possible to further increase the resolution. The liquid discharge head 1 of the present example is configured as illustrated in FIG. 2 to narrow the interval between the adjacent nozzles N. FIG. 2 is a cross-sectional view taken in a direction generally along the moving direction A. In the liquid discharge head 1 of the present example, the same ink is supplied from an ink cartridge (not illustrated) to both a nozzle row 12A and a nozzle row 12B of the nozzle rows 12, and the same ink can be discharged from the nozzles N of the nozzle row 12A and the nozzles N of the nozzle row 12B. The ink flows in a flow direction F inside the liquid discharge head 1. Specifically, in both the nozzle row 12A and the nozzle row 12B, the ink flowing from the ink cartridge in the flow direction F is supplied to a pressure chamber 41 including the nozzle N, via a flow path 51A corresponding to a second through-hole 22 of a sealing plate 20 described later, and a flow path 51B corresponding to a through-hole of a cavity substrate 30 described later, both of which partially form a flow path 51. Then, when pressure is applied to the pressure chamber 41, the ink is discharged from the nozzle N in a discharge direction D.

The detailed configuration of the liquid discharge head 1 of the present example will be further described with reference to FIG. 2. As illustrated in FIG. 2, the liquid discharge head 1 of the present example includes the sealing plate 20, the cavity substrate 30, and the flow path substrate 40.

The sealing plate 20 is a single crystal silicon substrate at least a part of which constitutes the flow path 51 of liquid. In addition, the sealing plate 20 includes a first surface 20a and a second surface 20b that is a surface opposite to the first surface 20a as substrate surfaces, and includes a first through-hole 21 including an inclined side wall 21a inclined with respect to the first surface 20a and the second surface 20b. In addition, the sealing plate 20 includes the second through-hole 22 that constitutes the flow path 51 and that includes a side wall constituted by a vertical side wall 22a more nearly vertical to the first surface 20a and the second surface 20b than the inclined side wall 21a is. Then, the second through-hole 22 is a part of the flow path 51, and serves as an ink reservoir. As described above, since the second through-hole 22 including the side wall constituted by the vertical side wall 22a that is nearly vertical serve as the ink reservoir, it is possible to prevent or restrict the sealing plate 20 from becoming large in a planar direction in which the substrate surface expands, and it is possible to reduce a size of the liquid discharge head 1.

The cavity substrate 30 includes a third surface 30a and a fourth surface 30b that is a surface opposite to the third surface 30a as substrate surfaces, and is bonded to the sealing plate 20 by the third surface 30a being bonded to the second surface 20b. Similar to the sealing plate 20, the cavity substrate 30 of the present example is also a single crystal silicon substrate, but is not limited to be the single crystal silicon substrate. Further, a piezoelectric element 32 and electrode films 33 and 34 as conductive portions electrically coupled to the piezoelectric element 32 are formed as an electrode portion 31 at the third surface 30a, and at least a part of the fourth surface 30b constitutes the flow path 51. Further, the sealing plate 20 is provided with a control IC 28, and the electrode film 33 is coupled to the control integrated circuit (IC) 28 via a flexible flat cable (FPC) 29. Note that, a piezoelectric element accommodation chamber 23 is provided in a region of the sealing plate 20 corresponding to a formation position of the electrode portion 31. The electrode film 33 extends from the piezoelectric element accommodation chamber 23 to the first through-hole 21. From another viewpoint, a tape carrier package (TCP) is chip-on-flex (COF) mounted at the first through-hole 21. In the COF mounting, a dedicated tool is used for thermal compression bonding of the TCP, but by widening the first surface 20a side and narrowing the second surface 20b side at the time of the COF mounting, it is possible to prevent or restrict the sealing plate 20 or the cavity substrate 30 from becoming large in the planar direction, and it is possible to reduce the size of the liquid discharge head 1.

The flow path substrate 40 includes a fifth surface 40a and a sixth surface 40b that is a surface opposite to the fifth surface 40a as substrate surfaces, and is bonded to the cavity substrate 30 by the fifth surface 40a being bonded to the fourth surface 30b. Similar to the sealing plate 20 and the cavity substrate 30, the flow path substrate 40 of the present example is also a single crystal silicon substrate. Further, the flow path substrate 40 is provided with the pressure chamber 41 at a position facing the electrode portion 31 via the cavity substrate 30, and the pressure chamber 41 is provided with the nozzle N that discharges the ink in the discharge direction D as described above. When the electrode portion 31 is energized, the piezoelectric element 32 is deformed and the cavity substrate 30 vibrates, so that pressure is applied to the pressure chamber 41, and the ink in the pressure chamber 41 is discharged from the nozzle N in the discharge direction D.

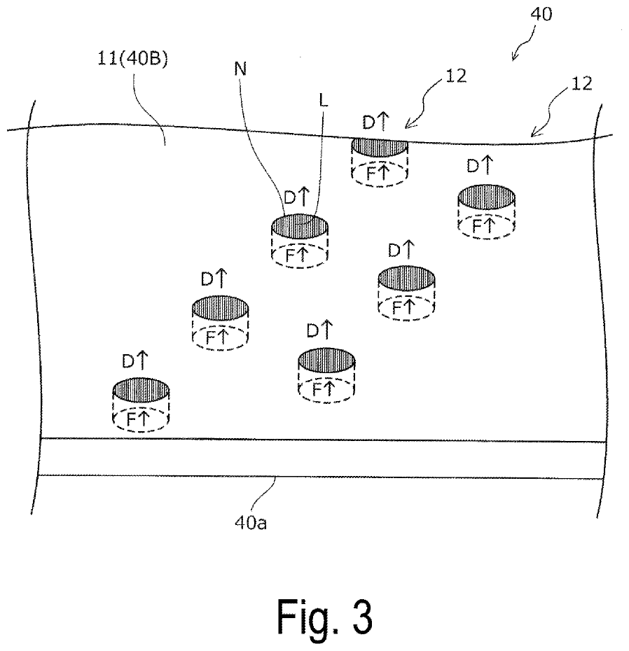

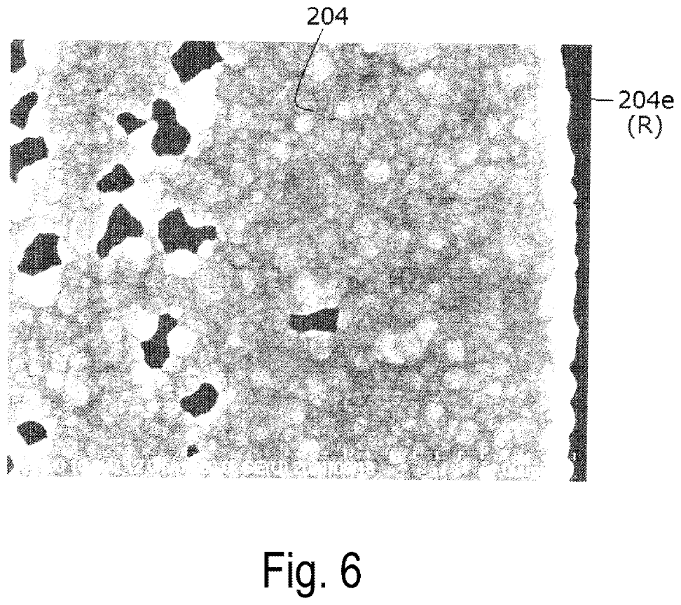

The flow path substrate 40 will be described further in detail below with reference to FIG. 3. As described above, the flow path substrate 40 of the present example is the single crystal silicon substrate at least part of which is provided with the nozzle N constituting the flow path 51 of the ink. Then, the nozzle N constitutes a part of the flow path 51, and is a through-hole extending through the flow path substrate 40 in a direction intersecting the fifth surface 40a and the sixth surface 40b as the substrate surfaces as illustrated in FIG. 3. Here, the nozzle N as the through-hole is formed by metal-assisted chemical etching (MACE), and as illustrated in FIG. 3, includes a striped portion L in which a concave portion and a convex portion along the flow direction F of the ink extend. As described above, in the flow path substrate 40 of the present example, the striped portion L along the flow direction F of the ink is formed with a narrow formation pitch by MACE, and a flow of the liquid in the nozzle N can be improved by the striped portion L along the flow direction F of the ink with the narrow formation pitch. Note that, the striped portion L of the present example is configured by both the concave portion and the convex portion corresponding to irregularities R of FIG. 6 described later, but it is sufficient that the striped portion L is configured by at least one of the concave portion or the convex portion along the flow direction F of the ink.

Here, each nozzle N is provided with the striped portion L in which at least one of a plurality of the concave portions or a plurality of the convex portions are provided side by side when viewed in the discharge direction D corresponding to an extending direction of the nozzle N, but a formation pitch of the adjacent concave portions or the adjacent convex portions may be from 10 nm to 300 nm. This is because when the formation pitch of the striped portion is too large, there is a possibility that turbulence occurs or there is a possibility that bubbles, foreign matter, and the like remain, in the concave portion or the convex portion, and when the formation pitch of the striped portion is too small, there is a possibility that an effect of forming the striped portion is insufficient. By setting the formation pitch of the striped portion L to be from 10 nm to 300 nm, it is possible to suitably improve a flow of the ink in the nozzle N. Note that, setting the formation pitch of the striped portion L to be from 10 nm to 300 nm means, in other words, that the irregularities R in FIG. 6 are irregularities from 10 nm to 300 nm, which corresponds to a grain size of the Au film 204.

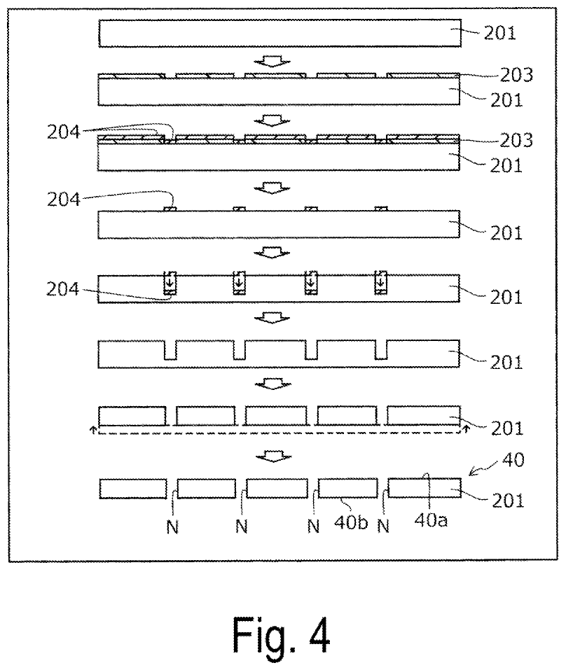

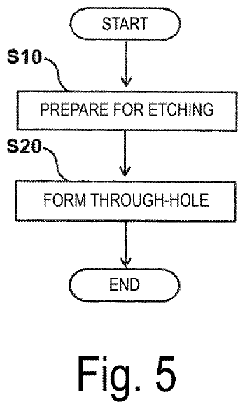

Next, a method for manufacturing the flow path substrate 40 of the present example will be described with reference to FIGS. 4 to 7. As illustrated in FIG. 5, in the method for manufacturing the sealing plate 20 of the present example, first, an etching preparation step of step S10 is performed. In the etching preparation step of Step S10, first, a single crystal silicon substrate 201 illustrated in a top diagram of FIG. 4 is patterned with a resist 203 by photolithography, as illustrated in a second diagram from the top of FIG. 4. Then, the Au film 204 that is a film made of gold serving as a catalyst film of MACE is formed as illustrated in a third diagram from the top of FIG. 4, and lift-off formation is performed as illustrated in a fourth diagram from the top of FIG. 4. Note that, in the present example, the Au film 204 is formed by depositing Au on an entire lower surface in the diagram, but the formation of the Au film 204 is not limited to such a method. Here, when forming the Au film 204, by adjusting film forming conditions such as ultimate vacuum of a vacuum apparatus to be used, and a film forming rate, or by performing heating processing or the like, as illustrated in FIG. 6, treatment is performed so as to form the irregularities R having a desired size from 10 nm to 300 nm at an edge portion 204e of the Au film 204. Note that, when forming the further larger irregularities R, by forming irregularities on the pattern side of the resist 203 by photolithography, the irregularities can be formed along the pattern shape, so that there is no particular upper limit of the irregularities. Up to this point corresponds to the etching preparation step of S10.

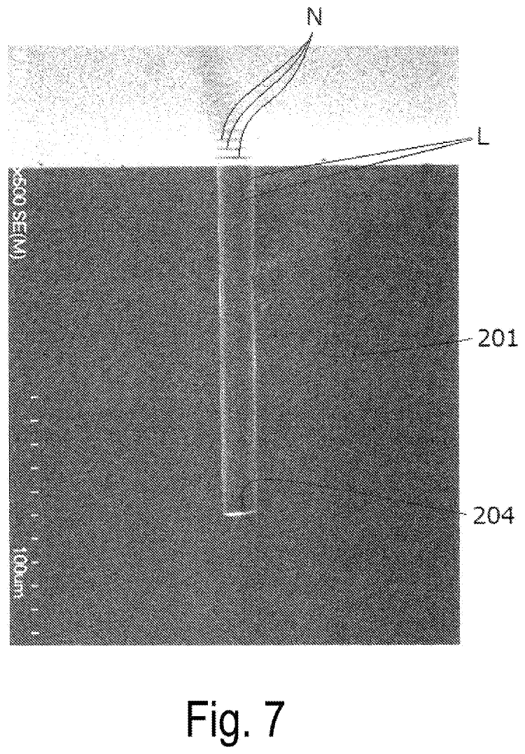

Next, a through-hole forming step in step S20 of FIG. 5 is performed. Specifically, a through-hole corresponding to the nozzle N is formed by MACE using an aqueous hydrogen fluoride solution that is a solution in which hydrogen fluoride and hydrogen peroxide are mixed, as illustrated in a fifth diagram from the top of FIG. 4. Then, when the Au film 204 is etched, a state illustrated in a sixth diagram from the top of FIG. 4 is obtained, and when this is thinned by removing a lower surface side in the diagram by grinding, polishing, or the like as illustrated in a seventh diagram from the top of FIG. 4, the flow path substrate 40 of the present example is completed as illustrated in a bottom diagram of FIG. 4. Note that, FIG. 7 is a photograph that corresponds to the fifth diagram from the top of FIG. 4. As illustrated in FIG. 6, by forming the irregularities R at the edge portion 204e of the Au film 204, when MACE is performed, the striped portion L along the flow direction F of the ink is formed at the nozzle N.

As described above, in the etching preparation step of step S10, of the method for manufacturing the flow path substrate 40 that is the single crystal silicon substrate of the present example, the Au film 204 that is the catalyst film is formed in an etching target region of the fifth surface 40a as a catalyst film forming surface of a substrate surface of the flow path substrate 40. Then, in the through-hole forming step of Step S20, the flow path substrate 40 with the Au film 204 formed is brought into contact with an aqueous hydrogen fluoride solution as an etching solution to etch the etching target region, thereby forming the nozzle N as a through-hole extending through the flow path substrate 40 in a direction intersecting the substrate surface. Here, as described above, in the through-hole forming step of step S20, the striped portion L is formed in which at least one of the concave portion or the convex portion along the extending direction of the nozzle N corresponding to the flow direction F of the ink extends. By performing such a method for manufacturing the flow path substrate 40, it is possible to form the elaborate striped portion L along the extending direction with the narrow formation pitch at the nozzle N. Therefore, it is possible to improve the flow of the ink in the nozzle N by performing the method for manufacturing the flow path substrate 40 of the present example.

In addition, as described above, in the method for manufacturing the flow path substrate 40 of the present example, the nozzle N is formed by MACE in the through-hole forming step of step S20. For this reason, it is possible to suitably form the elaborate striped portion L along the extending direction with the narrow formation pitch at the nozzle N. Therefore, it is possible to improve the flow of the ink in the nozzle N.

Here, while forming the Au film 204 in the etching preparation step of step S10, the method thereof is not particularly limited, but the Au film 204 may be formed by an electroless plating method or a vapor deposition method. This is because the flow path substrate 40 can be manufactured particularly easily and with high accuracy, by forming the Au film 204 by the electroless plating method or the vapor deposition method.

In addition, in the method for manufacturing the flow path substrate 40 of the present example, the etching preparation step of step S10 includes forming a pattern with a resist illustrated in the second diagram from the top of FIG. 4 before the formation of the Au film 204 illustrated in the third diagram from the top of FIG. 4, and further includes removing the resist illustrated in the fourth diagram from the top of FIG. 4 after the formation of the Au film 204 illustrated in the third diagram from the top of FIG. 4. By adopting such a method, it is possible to easily manufacture the flow path substrate 40.

In addition, in the method for manufacturing the flow path substrate 40 of the present example, in the through-hole forming step of step S20, the nozzle N is formed by removing the Au film 204 before the single crystal silicon substrate 201 is penetrated as illustrated in the sixth diagram from the top of FIG. 4, and removing a part of the substrate surface on the sixth surface 40b side opposite to the catalyst film forming surface (fifth surface 40a) to a position where the single crystal silicon substrate 201 is penetrated as illustrated in the seventh diagram from the top of FIG. 4. By adopting such a method, the flow path substrate 40 can be easily manufactured.

In addition, in the through-hole forming step of step S20 in the method for manufacturing the flow path substrate 40 of the present example, the side wall of the nozzle N may be constituted by the vertical side wall 22a angled at 90° plus or minus 2° with respect to the substrate surface of the flow path substrate 40. This is because by adopting such a configuration, it is possible to suppress expansion of the substrate surface, and to make the flow path substrate 40 small.

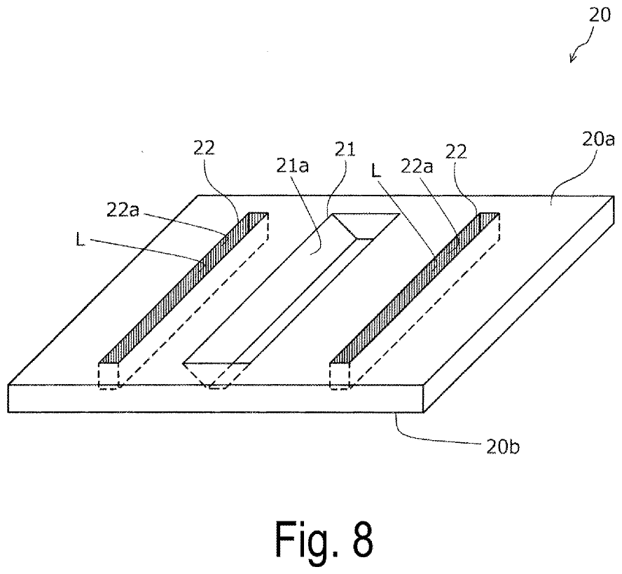

Next, the sealing plate 20 will be described further in detail with reference to FIG. 8. As described above, the sealing plate 20 of the present example is the single crystal silicon substrate at least a part of which is provided with the second through-hole 22 constituting the flow path 51 of the ink. Then, the second through-hole 22 constitutes a part of the flow path 51, and is a through-hole extending through the sealing plate 20 in a direction intersecting the first surface 20a and the second surface 20b as the substrate surfaces as illustrated in FIG. 8. Here, the second through-hole 22 as the through-hole is formed by MACE, and as illustrated in FIG. 8, includes the striped portion L in which a concave portion and a convex portion along the flow direction F of the ink extend. Then, a formation pitch of the striped portion L of the second through-hole 22 is the same as the formation pitch of the striped portion L of the nozzle N. That is, the description of the nozzle N that is the through-hole of the above flow path substrate 40 can be adapted to the sealing plate 20 by replacing the nozzle N with the second through-hole 22.

Here, in the sealing plate 20 of the present example, the first through-hole 21 is formed by crystal anisotropic etching, and the second through-hole 22 is formed by MACE. By forming a through-hole by MACE, it is possible to form a through-hole including a side wall more nearly vertical than when a through-hole is formed by crystal anisotropic etching. Therefore, the side wall of the second through-hole 22 can be constituted by the vertical side wall 22a substantially vertical to the first surface 20a and the second surface 20b that are the substrate surfaces. By forming the sealing plate 20 as described above, a single crystal silicon substrate having elaborate structure can be manufactured, and the liquid discharge head 1 that is small and has a high resolution can be manufactured. Further, by forming the first through-hole 21 by crystal anisotropic etching and forming the second through-hole 22 by metal-assisted chemical etching, etching can be performed in an all-wet state, without using dry etching that uses a large amount of greenhouse gases. For this reason, by forming the sealing plate 20 as described above, it is possible to improve productivity, and reduce an amount of electric power and use of greenhouse gases accompanying manufacturing.

Here, an angle formed by the vertical side wall 22a with respect to the substrate surface may be 90° plus or minus 2°, as described above. This is because by using a single crystal silicon wafer in which Miller indices (indices of crystal plane) of the substrate surface that is a front surface are (100) for the sealing plate 20, and devising composition of an etching solution, it is possible to manage vertical etching by MACE, for example, a thickness of the sealing plate 20 in a range of about 400 μm, and to secure verticality.

Further, an angle formed by the inclined side wall 21a with respect to the substrate surface may be from 45.0° to 54.7°. 54.7° is an angle formed by a front surface portion of the first surface 20a of the sealing plate 20 having the Miller indices (indices of crystal plane) of (100) and a crystal plane having Miller indices (indices of crystal plane) of (111) where etching progresses the slowest, and is a value of COS⁻¹ (⅓^{1/2}) in calculation. In addition, 45° is an angle formed by a crystal plane that is stable next and has Miller indices (indices of crystal plane) of (110), and is a value of COS⁻¹ (½^{1/2}). Note that, as compared with the case where the angle is 45°, an etching surface is more stable when the angle is 54.7°, and an entire size of the sealing plate 20 can be reduced.

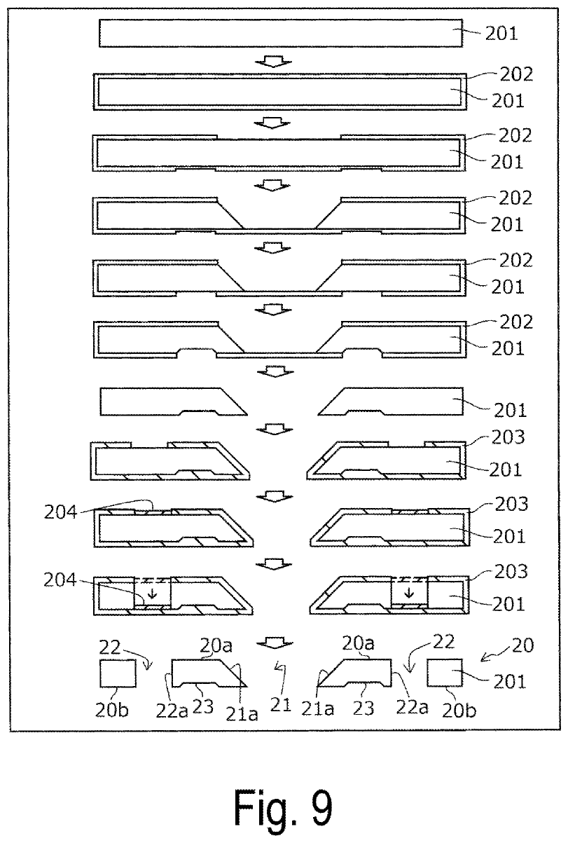

Next, the method for manufacturing the sealing plate 20 of the present example will be described with reference to FIGS. 5 and 9. That is, a flowchart of the method for manufacturing the sealing plate 20 of the present example is the same as the flowchart of the method for manufacturing the flow path substrate 40 of the present example illustrated in FIG. 5. In the method for manufacturing the sealing plate 20 of the present example, first, an oxide film 202 represented by SiO₂ is formed at the single crystal silicon substrate 201 illustrated in a top diagram of FIG. 9, as illustrated in a second diagram from the top of FIG. 9. Then, as illustrated in a third diagram from the top of FIG. 9, patterning is performed using a resist by photolithography. Here, the patterning is performed such that the oxide film 202 is not present in a region of an upper surface in the diagram of the single crystal silicon substrate 201 corresponding to the first through-hole 21, and the oxide film 202 is thinly present in a region of a lower surface in the diagram of the single crystal silicon substrate 201 corresponding to the piezoelectric element accommodation chamber 23. Then, as illustrated in a fourth diagram from the top of FIG. 9, a through-hole corresponding to the first through-hole 21 is formed by crystal anisotropic etching, which is wet etching using potassium hydroxide (KOH).

Next, as illustrated in a fifth diagram from the top of FIG. 9, the oxide film 202 in the region of the lower surface in the diagram of the single crystal silicon substrate 201 corresponding to the piezoelectric element accommodation chamber 23 is etched, and then a concave portion corresponding to the piezoelectric element accommodation chamber 23 is formed by crystal anisotropic etching using KOH as illustrated in the fifth diagram from the top of FIG. 9. Then, as illustrated in a seventh diagram from the top of FIG. 9, the entire oxide film 202 is removed by etching, and as illustrated in an eighth diagram from the top of FIG. 9, patterning is performed using the resist 203 by photolithography. Here, the patterning is performed so that the resist 203 does not exist in a region of the upper surface in the diagram of the single crystal silicon substrate 201 corresponding to the second through-hole 22. Then, as illustrated in a ninth diagram from the top of FIG. 9, the Au film 204, which is a film made of gold serving as a catalyst film of MACE, is formed in the region of the upper surface in the diagram of the single crystal silicon substrate 201 corresponding to the second through-hole 22. With respect to the Au film 204 in the method for manufacturing the sealing plate 20 of the present example, treatment is performed so that the irregularities R are formed at the edge portion 204e of the Au film 204, similarly to the Au film 204 in the method for manufacturing the above flow path substrate 40. Up to this point corresponds to the etching preparation step of the step S10.

Next, the through-hole forming step in step S20 of FIG. 5 is performed. Specifically, a through-hole corresponding to the second through-hole 22 is formed by MACE using an aqueous hydrogen fluoride solution, as illustrated in a tenth diagram from the top of FIG. 9. Then, when the Au film 204 is etched and the resist 203 is removed, the sealing plate 20 of the present example is completed, as illustrated in a bottom diagram of FIG. 9.

As described above, in the etching preparation step of step S10, of the method for manufacturing the sealing plate 20 that is the single crystal silicon substrate of the present example, the Au film 204 that is the catalyst film is formed in an etching target region of the first surface 20a as a catalyst film forming surface of the substrate surface of the sealing plate 20. Then, in the through-hole forming step of Step S20, the sealing plate 20 with the Au film 204 formed is brought into contact with an etching solution to etch the etching target region, thereby forming the second through-hole 22 as the through-hole extending through the sealing plate 20 in a direction intersecting the substrate surface. Here, as described above, in the through-hole forming step of step S20, the striped portion L is formed in which at least one of the concave portion or the convex portion along an extending direction of the second through-hole 22 extends. By performing such a method for manufacturing the sealing plate 20, it is possible to form the elaborate striped portion L along the extending direction with a narrow formation pitch at the second through-hole 22. Therefore, it is possible to improve a flow of the ink in the second through-hole 22 by performing the method for manufacturing the sealing plate 20 of the present example. That is, the description of the forming method of the nozzle N that is the through-hole of the method for manufacturing the above flow path substrate 40 can be adapted to the method for manufacturing the sealing plate 20 by replacing the nozzle N with the second through-hole 22.

In addition, as illustrated in FIG. 9, the method for manufacturing the sealing plate 20 of the present example includes forming the first through-hole 21, which is an inclined through-hole including the inclined side wall 21a more inclined than the vertical side wall 22a of the second through-hole 22 with respect to the substrate surface, by subjecting a crystal anisotropic etching target region of the substrate surface to crystalline anisotropic etching. Therefore, for example, when a constituent member is disposed at the first through-hole 21, or the like, by forming the first through-hole 21 as the inclined through-hole that is widened toward an end as in the present example, the constituent member can be suitably disposed at the inclined through-hole.

Here, while forming the first through-hole 21 as the inclined through-hole, an alkaline aqueous solution can be used as an etching solution. By using the alkaline aqueous solution as the etching solution, the inclined through-hole can be easily formed. Note that, as the alkaline aqueous solution as the etching solution, for example, in addition to the potassium hydroxide aqueous solution used in the present example, a tetramethyl ammonium hydroxide (THAM) aqueous solution or the like can be suitably used, but no particular limitation is imposed thereon. The potassium hydroxide aqueous solution is inexpensive, and thus can be used, for example, for silicon substrate processing that does not involve a semiconductor. On the other hand, the THAM aqueous solution does not contain mobile ions such as Na and K, and thus can be used, for example, in crystal anisotropic etching processing for silicon substrate processing involving a semiconductor.

Next, a method for manufacturing the entire liquid discharge head 1 using the sealing plate 20 and the flow path substrate 40 formed as described above will be described with reference to a flowchart of FIG. 6. First, in step S110, the sealing plate 20 is formed. The sealing plate 20 is formed as described above. Next, in step S120, the cavity substrate 30 is formed using an existing manufacturing method or the like, and in step S130, the sealing plate 20 and the cavity substrate 30 are bonded to each other. Note that, the order of steps S110 and S120 may be reversed, or may be performed simultaneously.

Thereafter, in step S140, an ink protective film made of titanium oxide (TiOx), hafnium oxide (HfOx), or the like is formed as film by a chemical vapor deposition (CVD) method or the like to form the ink protective film. In addition, in step S150, the flow path substrate 40 is formed. The formation of the flow path substrate 40 is as described above. Here, step S150 may be performed before step S140. Then, in step S160, the flow path substrate 40 is bonded to the substrate in which the sealing plate 20 and the cavity substrate 30 are bonded. Then, in step S170, this is divided into chips by laser scribing or the like, and in step S180, the TCP constituting the conductive portion is COF-mounted. Finally, in step S190, a case component is mounted to complete the manufacture of the liquid discharge head 1. In such a method, since a chip of the liquid discharge head 1 can be assembled in a wafer state, quality can be stabilized, and mass production becomes easy.

As described above, the liquid discharge head 1 of the present example includes at least one of the sealing plate 20 or the flow path substrate 40 as the above single crystal silicon substrate. Further, the cavity substrate is included that includes the third surface 30a, which is a conductive portion forming surface at which the piezoelectric element 32 and the electrode films 33 and 34 that are the conductive portions electrically coupled to the piezoelectric element 32 are formed, and the fourth surface 30b at least a part of which constitutes the flow path 51 and that is a flow path forming surface opposite to the third surface 30a. Then, the third surface 30a or the fourth surface 30b is bonded to the substrate surface of at least one of the sealing plate 20 or the flow path substrate 40, and thus the flow path 51 of the fourth surface 30b communicates with the second through-hole 22 or the nozzle N, which is the through-hole. As described above, the flow path 51 of the flow path forming surface is configured to communicate with the through-hole by the conductive portion forming surface being bonded to the substrate surface, by at least one of the sealing plate 20 or the flow path substrate 40 as the single crystal silicon substrate, and the cavity substrate, and thus it is possible to manufacture the liquid discharge head 1 in which the flow of the liquid in the through-hole is improved.

The present disclosure is not limited to the present examples described above, and can be realized in various configurations without departing from the gist of the present disclosure. For example, a single crystal silicon substrate such as the sealing plate 20 described above can be used in a micropump or the like, other than the liquid discharge head. Further, appropriate replacements or combinations may be made to the technical features in the present examples which correspond to the technical features in the aspects described in the SUMMARY section to solve some or all of the problems described above or to achieve some or all of the advantageous effects described above. Additionally, when the technical features are not described herein as essential technical features, such technical features may be deleted appropriately.

What is claimed is:

1. A single crystal silicon substrate at least a part of which constitutes a flow path for liquid, the single crystal silicon substrate comprising
a through-hole constituting a part of the flow path and extending through the single crystal silicon substrate in a direction intersecting a substrate surface of the single crystal silicon substrate, wherein
the through-hole is formed by metal-assisted chemical etching, and includes a striped portion in which at least one of a concave portion or a convex portion along a direction in which the liquid flows extends.

2. The single crystal silicon substrate according to claim 1, wherein
at least one of a plurality of the concave portions or a plurality of the convex portions are provided side by side at the through-hole when viewed in an extending direction of the through-hole and
a formation pitch between the concave portions adjacent to each other or between the convex portions adjacent to each other is from 10 nm to 300 nm.

3. A liquid discharge head, comprising:
the single crystal silicon substrate according to claim 1; and
a cavity substrate including a conductive portion forming surface at which a piezoelectric element and a conductive portion electrically coupled to the piezoelectric element are formed, and a flow path forming surface at least a part of which constitutes the flow path and that is opposite to the conductive portion forming surface, wherein
the conductive portion forming surface or the flow path forming surface is bonded to the substrate surface with the flow path of the flow path forming surface communicating with the through-hole.

4. A method for manufacturing a single crystal silicon substrate, the method comprising:
forming a catalyst film in an etching target region of a catalyst film forming surface of a substrate surface of a single crystal silicon substrate; and
forming a through-hole extending through the single crystal silicon substrate in a direction intersecting the substrate surface, by bringing the single crystal silicon substrate with the catalyst film formed into contact with an etching solution to etch the etching target region, wherein
while forming the through-hole, a striped portion is formed in which at least one of a concave portion or a convex portion along an extending direction of the through-hole extends.

5. The method for manufacturing a single crystal silicon substrate according to claim 4, wherein
while forming the through-hole, the through-hole is formed by metal-assisted chemical etching.

6. The method for manufacturing a single crystal silicon substrate according to claim 5, wherein
while forming the catalyst film, the catalyst film is formed by an electroless plating method or a vapor deposition method.

7. The method for manufacturing a single crystal silicon substrate according to claim 4, the method further comprising:
forming a pattern with a resist before the formation of the catalyst film; and
removing the resist after the formation of the catalyst film.

8. The method for manufacturing a single crystal silicon substrate according to claim 4, wherein
a side wall of the through-hole is constituted by a vertical side wall angled at 90° plus or minus 2° with respect to the substrate surface.

9. The method for manufacturing a single crystal silicon substrate according to claim 4, wherein
while forming the through-hole, the through-hole is formed by removing the catalyst film before the single crystal silicon substrate is penetrated, and removing a part of the substrate surface on a side of a surface opposite to the catalyst film forming surface to a position where the single crystal silicon substrate is penetrated.

10. The method for manufacturing a single crystal silicon substrate according to claim 4, the method further comprising
forming an inclined through-hole including an inclined side wall more inclined than a side wall of the through-hole with respect to the substrate surface, by subjecting a crystal anisotropic etching target region of the substrate surface to crystal anisotropic etching.

11. The method for manufacturing a single crystal silicon substrate according to claim 10, wherein
while forming the inclined through-hole, an alkaline aqueous solution is used as the etching solution.
